(19) United States
(12) Patent Application Publication
(10) Pub. No.: US 2026/0333979 A1
(43) Pub. Date: Oct. 22, 2026

(54) LIGHT-EMITTING ELEMENT

(71) Applicant: NICHIA CORPORATION, Anan-shi (JP)

(72) Inventor: Hiroshi FUJIMOTO, Anan-shi (JP)

(73) Assignee: NICHIA CORPORATION, Anan-shi (JP)

(21) Appl. No.: 19/634,954

(22) Filed: Mar. 31, 2026

(30) Foreign Application Priority Data
Apr. 17, 2025 (JP) 2025-067838
Dec. 15, 2025 (JP) 2025-250852

(51) Int. Cl. H10H 29/80; H10H 29/14

(52) U.S. Cl. CPC H10H 29/842; H10H 29/14; H10H 29/8321; H10H 29/8323

(57) ABSTRACT

A light-emitting element includes: a substrate; a first light-emitting portion and a second light-emitting portion disposed on the substrate, the first light-emitting portion and the second light-emitting portion each including a first semiconductor layer, a second semiconductor layer, and an active layer; a first insulating layer disposed on a portion of the second semiconductor layer of the first light-emitting portion; a light-transmissive conductive layer disposed on the first insulating layer and on the second semiconductor layer of the first light-emitting portion; a first electrode disposed on the first semiconductor layer of the first light-emitting portion and electrically connected to the first semiconductor layer of the first light-emitting portion; a second electrode electrically connected to the second semiconductor layer of the second light-emitting portion; and a third electrode electrically connecting the first light-emitting portion and the second light-emitting portion.

### CROSS-REFERENCE TO RELATED APPLICATIONS

This application is based upon and claims priority to Japanese Patent Application No. 2025-067838, filed on Apr. 17, 2025, and Japanese Patent Application No. 2025-250852, filed on Dec. 15, 2025. The entire contents of these applications are incorporated herein by reference.

### F IELD

The present disclosure relates to a light-emitting element.

### BACKGROUND

Japanese Unexamined Patent Application Publication No. H11-150303 discloses a light-emitting part in which a plurality of semiconductor light-emitting elements are formed on a substrate and are electrically connected through internal wiring.

### SUMMARY

Such light-emitting elements are desired to have higher reliability. An object of the present disclosure is to provide a more reliable light-emitting element.

A light-emitting element according to one embodiment in the present invention includes a substrate, a first light-emitting portion and a second light-emitting portion, a first insulating layer, a light-transmissive conductive layer, a first electrode, a second electrode, and a third electrode. The first light-emitting portion and the second light-emitting portion are disposed on the substrate. Each of the first light-emitting portion and the second light-emitting portion includes a first semiconductor layer of a first conduction type, a second semiconductor layer of a second conduction type, and an active layer between the first semiconductor layer and the second semiconductor layer. The first insulating layer is disposed on a portion of the second semiconductor layer of the first light-emitting portion. The light-transmissive conductive layer is disposed on the first insulating layer and on the second semiconductor layer of the first light-emitting portion. The first electrode is disposed on the first semiconductor layer of the first light-emitting portion and electrically connected to the first semiconductor layer of the first light-emitting portion. The second electrode is disposed on the second semiconductor layer of the second light-emitting portion and electrically connected to the second semiconductor layer of the second light-emitting portion. The third electrode is disposed on the second semiconductor layer of the first light-emitting portion and on the first semiconductor layer of the second light-emitting portion to electrically connect the first light-emitting portion and the second light-emitting portion. The third electrode has a first region located in a region where the first insulating layer is disposed and in contact with the light-transmissive conductive layer, a second region located in a region where the first insulating layer is not disposed and in contact with the light-transmissive conductive layer, and a third region in contact with the first semiconductor layer of the second light-emitting portion. The second region is located between the first region and the third region in a top view. A width of the third electrode in the second region is greater than a width of the third electrode in the first region in a top view.

With the light-emitting element according to one embodiment of the present disclosure, a more reliable light-emitting element can be provided.

### BRIEF DESCRIPTION OF DRAWINGS

FIG. 1 is a schematic top view illustrating the configuration of a light-emitting element according to a first embodiment.

FIG. 2 is a schematic cross-sectional view taken along the line II-II of FIG. 1.

### DETAILED DESCRIPTION

Light-emitting elements of certain embodiments will be described below with reference to the accompanying drawings. Unless specifically stated otherwise, descriptions of the sizes, materials, shapes, and relative positions of constituent units in the embodiment described below are not intended to put limitations to those descriptions, but are rather merely examples for description. Sizes or positional relationships of members illustrated in each drawing may be exaggerated in order to clarify the descriptions. Furthermore, in the descriptions below, the same name or the same reference numeral represents the same member or a similar material, and its duplicative description will be omitted as appropriate. Also, cross-sectional end views showing only cut surfaces of members may be used as cross-sectional views.

In the descriptions below, terms representing particular directions or positions (such as “up/upper,” “down/lower,” and other terms containing the meanings of these terms) may be used. These terms are used merely for the sake of ease of explanation, representing relative directions or relative positions in the reference drawings. As far as the relative directions or positions mentioned by the terms “upper,” “lower,” and the like designate the same directions or positions in the reference drawings, drawings other than shown in the present disclosure, actual products, and the like are not necessarily the same arrangement as shown in the reference drawings. The positional relationship represented as “on” (or “below”) in the present specification includes, for example, assuming that there are two members, the case in which the two members are in contact with each other and the case in which the two members are not in contact with each other but one member is located above (or below) the other member. The term “top view” as used in the present specification refers to observation of the upper surface of the light-emitting element.

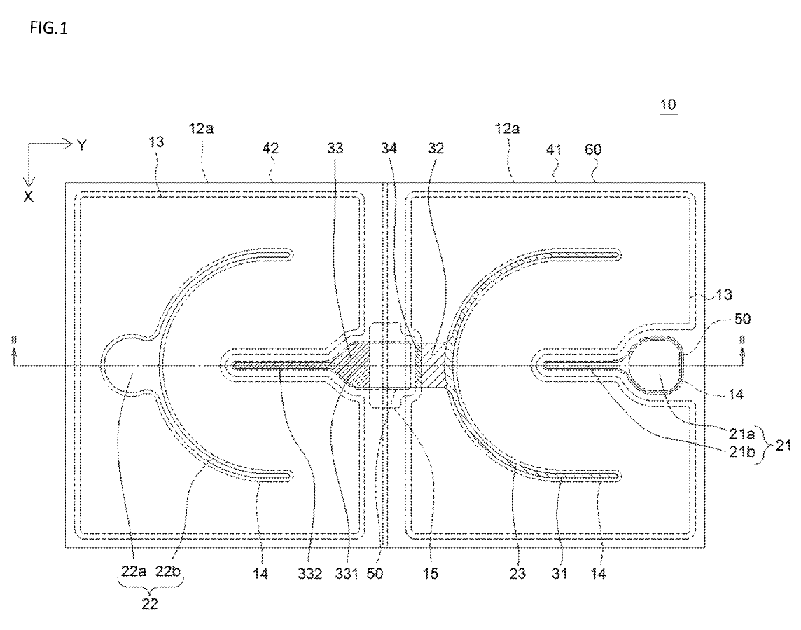

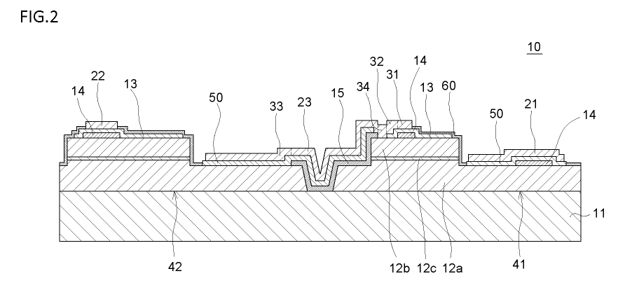

A light-emitting element 10 of the present embodiment will be described below in detail with reference to FIGS. 1 and 2 . FIG. 1 is a schematic top view illustrating the configuration of the light-emitting element 10 according to the present embodiment. FIG. 2 is a schematic cross-sectional view taken along the line II-II of FIG. 1.

The light-emitting element 10 of the present embodiment includes a substrate; a first light-emitting portion 41 and a second light-emitting portion 42 disposed on the substrate, the first light-emitting portion 41 and the second light-emitting portion 42 each including a first semiconductor layer 12a of a first conduction type, a second semiconductor layer 12b of a second conduction type, and an active layer 12c between the first semiconductor layer 12a and the second semiconductor layer 12b. The light-emitting element 10 further includes a first insulating layer 14 disposed on a portion of the second semiconductor layer 12b of the first light-emitting portion 41; a light-transmissive conductive layer 13 disposed on the first insulating layer 14 and on the second semiconductor layer 12b of the first light-emitting portion 41; a first electrode 21 disposed on the first semiconductor layer 12a of the first light-emitting portion 41 and electrically connected to the first semiconductor layer 12a of the first light-emitting portion 41; a second electrode 22 disposed on the second semiconductor layer 12b of the second light-emitting portion 42 and electrically connected to the second semiconductor layer 12b of the second light-emitting portion 42; and a third electrode 23 disposed on the second semiconductor layer 12b of the first light-emitting portion 41 and on the first semiconductor layer 12a of the second light-emitting portion 42 to electrically connect the first light-emitting portion 41 and the second light-emitting portion 42. The third electrode 23 has a first region 31 located in a region where the first insulating layer 14 is disposed and in contact with the light-transmissive conductive layer 13, a second region 32 located in a region where the first insulating layer 14 is not disposed and in contact with the light-transmissive conductive layer 13, and a third region 33 in contact with the first semiconductor layer 12a of the second light-emitting portion 42. In a top view, the second region 32 is located between the first region 31 and the third region 33. In a top view, the width of the third electrode 23 in the second region 32 is greater than the width of the third electrode 23 in the first region 31.

In the light-emitting element 10 of present embodiment, the third electrode 23 has a first region 31 located within the region where the first insulating layer 14 is disposed, and the second region 32 located in a region where the first insulating layer 14 is not disposed. In the top view, the width of the third electrode 23 in the second region 32 is greater than the width of the third electrode 23 in the first region 31. This configuration reduces current concentration in the third electrode 23 in the second region 32 compared to when the width in the second region 32 is the same as that in the first region 31. As a result, current concentration in the light-transmissive conductive layer 13 whose thickness may be locally reduced near the boundary between the first region 31 and the second region 32 is reduced, thereby reducing the chance of breakage of the light-transmissive conductive layer 13 and improving the reliability of the light-emitting element 10.

Hereinafter, the structure of the light-emitting element 10 of present embodiment will be described in detail with reference to the Figs.

A substrate 11 supports the first light-emitting portion 41 and the second light-emitting portion 42. The substrate 11 may be a growth substrate for epitaxial growth of the first light-emitting portion 41 and the second light-emitting portion 42. In the case in which a nitride semiconductor is used for the first light-emitting portion 41 and the second light-emitting portion 42, for example, a sapphire (Al₂O₃) substrate can be used as the substrate 11. A plurality of projections may be arranged on the upper surface of the substrate 11.

The shape of the substrate 11 in a top view is a rectangular shape. In the case in which the substrate 11 has a rectangular shape, for example, the length of one side of the substrate 11 can be 200 μm or more and 1000 μm or less. The shape of the substrate 11 of the present embodiment in a top view is an elongated rectangular shape having short sides lying along a first direction X and long sides lying along a second direction Y. The first direction X and the second direction Y are orthogonal to each other. For example, the thickness of the substrate 11 can be 100 μm or more and 300 μm or less.

As shown in FIG. 2, the first light-emitting portion 41 and the second light-emitting portion 42 are disposed on the upper surface of the substrate 11. The first light-emitting portion 41 and the second light-emitting portion 42 each include the first semiconductor layer 12a of the first conduction type, the second semiconductor layer 12b of the second conduction type, and the active layer 12c between the first semiconductor layer 12a and the second semiconductor layer 12b. The upper surface of the first semiconductor layer 12a includes a region in which the active layer 12c and the second semiconductor layer 12b are disposed and a region in which the active layer 12c and the second semiconductor layer 12b are not disposed. The first conduction type is the p type or the n type. The second conduction type is a conduction type different from the first conduction type and is the p type or the n type. In the present embodiment, the first conduction type is the n type, and the second conduction type is the p type. When voltage is applied between the first electrode 21 disposed on the first semiconductor layer 12a of the first light-emitting portion 41 and the second electrode 22 disposed on the second semiconductor layer 12b of the second light-emitting portion 42, the active layers 12c of the first light-emitting portion 41 and the second light-emitting portion 42 each emit light.

For example, the light emitted from the active layer 12c is ultraviolet light or visible light. For example, the active layer 12c can emit blue light or green light as the visible light. The peak emission wavelength of the blue light is 430 nm or more and 490 nm or less. The peak emission wavelength of the green light is 500 nm or more and 540 nm or less. The peak emission wavelength of the ultraviolet light is 400 nm or less.

For example, the shape of the first light-emitting portion 41 in a top view and the shape of the second light-emitting portion 42 in a top view are rectangular shapes. The area of the first light-emitting portion 41 in a top view is substantially equal to the area of the second light-emitting portion 42 in a top view. This structure can reduce the imbalance in the emission distribution of the light-emitting element 10 caused by the difference between the area of the first light-emitting portion 41 in a top view and the area of the second light-emitting portion 42 in a top view. In the case in which the shape of the first light-emitting portion 41 in a top view is a rectangular shape, the length of one side of the first light-emitting portion 41 can be, for example, 100 μm or more and 500 μm or less. In the case in which the shape of the second light-emitting portion 42 in a top view is a rectangular shape, the length of one side of the second light-emitting portion 42 can be, for example, 100 μm or more and 500 μm or less. The area of the first light-emitting portion 41 in a top view may be different from the area of the second light-emitting portion 42 in a top view.

In a top view, the upper surface of the substrate 11 is located between the first light-emitting portion 41 and the second light-emitting portion 42. As shown in FIG. 1, in the second direction Y, a portion of the upper surface of the substrate 11 is located between the first light-emitting portion 41 and the second light-emitting portion 42. The portion of the upper surface of the substrate 11 is exposed from the first light-emitting portion 41 and the second light-emitting portion 42. In a top view, for example, the shortest distance between the first light-emitting portion 41 and the second light-emitting portion 42 can be 3 μm or more and 10 μm or less.

For example, a nitride semiconductor such as In_{X}Al_{Y}Ga_{1-X-Y}N (0 ≤ X, 0 ≤ Y, and X + Y < 1) can be used for the first semiconductor layer 12a, the second semiconductor layer 12b, and the active layer 12c. The first light-emitting portion 41 and the second light-emitting portion 42 are made of a nitride semiconductor.

As shown in FIGS. 1 and 2, in the first light-emitting portion 41, the light-transmissive conductive layer 13 is disposed on the first insulating layer 14 and on the second semiconductor layer 12b. The light-transmissive conductive layer 13 is in contact with and electrically connected to the second semiconductor layer 12b of the first light-emitting portion 41. In the second light-emitting portion 42, the light-transmissive conductive layer 13 is disposed on the first insulating layer 14 and on the second semiconductor layer 12b. The light-transmissive conductive layer 13 is in contact with and electrically connected to the second semiconductor layer 12b of the second light-emitting portion 42. In the first light-emitting portion 41, a portion of the light-transmissive conductive layer 13 is disposed between the third electrode 23 and the first insulating layer 14. In the second light-emitting portion 42, a portion of the light-transmissive conductive layer 13 is disposed between the second electrode 22 and the first insulating layer 14. The light-transmissive conductive layers 13 cover substantially the entire upper surfaces of the second semiconductor layers 12b of the first light-emitting portion 41 and the second light-emitting portion 42.

A conductive metal oxide can be used for the light-transmissive conductive layer 13. For example, an oxide containing at least one element selected from the group consisting of zinc (Zn), indium (In), tin (Sn), gallium (Ga), and titanium (Ti) can be used for the light-transmissive conductive layer 13. For example, indium tin oxide (ITO) or zinc oxide (ZnO) can be used for the light-transmissive conductive layer 13. ITO and ZnO each are highly transmissive to visible light and have high electrical conductivity; thus these materials are suitable materials for being disposed on substantially the entire upper surfaces of the second semiconductor layers 12b of the first light-emitting portion 41 and the second light-emitting portion 42.

The thickness of the light-transmissive conductive layer 13 is preferably reduced from the viewpoint of reducing light absorption by the light-transmissive conductive layer 13. For example, the thickness of the light-transmissive conductive layer 13 can be 30 nm or more and 150 nm or less, preferably 30 nm or more and 100 nm or less.

As shown in FIGS. 1 and 2 , the first insulating layer 14 is disposed on a portion of the second semiconductor layer 12b of the first light-emitting portion 41. The first insulating layer 14 is disposed on a portion between the third electrode 23 and the second semiconductor layer 12b of the first light-emitting portion 41. In this structure, a region that hardly conducts current is located directly below the third electrode 23 to reduce light emission in that region, so that light absorption by the third electrode 23 can be reduced. Further, this structure enables an increase in the current flowing through the second semiconductor layer 12b of the first light-emitting portion 41 located in a region other than a region directly below the first insulating layer 14, thereby allowing the light-emitting element 10 to efficiently emit light.

The first insulating layer 14 is in contact with the second semiconductor layer 12b of the first light-emitting portion 41. The refractive index of the first insulating layer 14 is preferably lower than the refractive index of the first semiconductor layer 12a. With this structure, the interface between the second semiconductor layer 12b of the first light-emitting portion 41 and the first insulating layer 14 can effectively reflect light traveling from the active layer 12c toward the first insulating layer 14 on the basis of the difference in refractive index and the Snell’s law. Accordingly, it is possible to reduce light absorption by the third electrode 23 and to improve the light extraction efficiency.

The first insulating layer 14 may be disposed between the first semiconductor layer 12a of the first light-emitting portion 41 and the first electrode 21. In this structure, a region that hardly conducts current is located directly below the first electrode 21 to reduce light emission in that region, so that light absorption by the first electrode 21 can be reduced. Further, this structure enables an increase in the current flowing through the first semiconductor layer 12a of the first light-emitting portion 41 located in a region other than a region directly below the first insulating layer 14, thereby allowing the light-emitting element 10 to efficiently emit light.

The first insulating layer 14 may be disposed between the second semiconductor layer 12b of the second light-emitting portion 42 and the second electrode 22. In this structure, a region that hardly conducts current is located directly below the second electrode 22 to reduce light emission in that region, so that light absorption by the second electrode 22 can be reduced. Further, this structure enables an increase in the current flowing through the second semiconductor layer 12b of the second light-emitting portion 42 located in a region other than a region directly below the first insulating layer 14, thereby allowing the light-emitting element 10 to efficiently emit light.

For example, the thickness of the first insulating layer 14 can be 50 nm or more and 400 nm or less. By setting the thickness of the first insulating layer 14 to 50 nm or more, the reflection by the interface between the first insulating layer 14 and the second semiconductor layer 12b can be effectively caused. By setting the thickness of the first insulating layer 14 to 400 nm or less, occurrence of breakage of the light-transmissive conductive layer 13 caused by the increase in the thickness of the first insulating layer 14 can be reduced. In the present specification, the thickness of each member refers to the maximum thickness of the member in a cross-sectional view.

For example, a silicon oxide film (SiO₂), a silicon oxynitride film (SiON), or a silicon nitride film (SiN) can be used for the first insulating layer 14. The first insulating layer 14 may have a single-layer structure or a multilayer structure including a plurality of insulating layers.

A second insulating layer 15 is disposed on a portion of the substrate 11 located between the first light-emitting portion 41 and the second light-emitting portion 42 in a top view and on the first semiconductor layer 12a of the first light-emitting portion 41. The second insulating layer 15 is in contact with the upper surface of the substrate 11, a lateral surface of the first light-emitting portion 41, and a lateral surface of the second light-emitting portion 42. The second insulating layer 15 is also disposed on the second semiconductor layer 12b of the first light-emitting portion 41. A portion of the third electrode 23 is disposed on the second insulating layer 15.

The thickness of the second insulating layer 15 is preferably greater than the thickness of the first insulating layer 14. The light-emitting element 10 includes a region in which only the third electrode 23 disposed on the second insulating layer 15 serves as the current path between the first light-emitting portion 41 and the second light-emitting portion 42, and the current is likely to be concentrated on the third electrode 23 on the second insulating layer 15. By making the thickness of the second insulating layer 15 greater than the thickness of the first insulating layer 14, the damage to the second insulating layer 15 caused by the concentration of current on the third electrode 23 can be reduced. Accordingly, the reliability of the light-emitting element 10 can be enhanced. For example, when the second insulating layer 15 is damaged, the third electrode 23 electrically connects the first semiconductor layer 12a of the first light-emitting portion 41 and the second semiconductor layer 12b of the first light-emitting portion 41, and the reliability of the light-emitting element may be reduced.

The thickness of the second insulating layer 15 can be twice or more and four times or less than the thickness of the first insulating layer 14. By making the thickness of the second insulating layer 15 twice or more than the thickness of the first insulating layer 14, electrical connection between the first semiconductor layer 12a of the first light-emitting portion 41 and the second semiconductor layer 12b of the first light-emitting portion 41 by the third electrode 23 is likely to be reduced. By making the thickness of the second insulating layer 15 four times or less than the thickness of the first insulating layer 14, breakage of the third electrode 23 caused by an excessively large thickness of the second insulating layer 15 can be reduced. For example, the thickness of the second insulating layer 15 can be 0.5 μm or more and 1.0 μm or less.

A light-transmissive and insulating material is preferably used for the second insulating layer 15. For example, a silicon oxide film, a silicon oxynitride film, or a silicon nitride film can be used for the second insulating layer 15.

As shown in FIGS. 1 and 2, the first electrode 21 is disposed on the first semiconductor layer 12a of the first light-emitting portion 41 and is electrically connected to the first semiconductor layer 12a of the first light-emitting portion 41. The first electrode 21 includes a first connection portion 21a and a first extending portion 21b extending from the first connection portion 21a. A portion of the first connection portion 21a is disposed on the first insulating layer 14. The first extending portion 21b is disposed on the first semiconductor layer 12a of the first light-emitting portion 41. The first connection portion 21a is a region connected to an external device via a wire or the like. As shown in FIG. 1, the first connection portion 21a has a substantially quadrilateral shape in a top view. The first extending portion 21b is an electrode used for efficiently diffusing the current supplied through the first connection portion 21a into the first semiconductor layer 12a of the first light-emitting portion 41. The first extending portion 21b extends from the first connection portion 21a along the second direction Y.

In a top view, the width of the first extending portion 21b is less than the width of the first connection portion 21a. For example, the width of the first connection portion 21a is 40 μm or more and 80 μm or less. For example, the width of the first extending portion 21b is 3 μm or more and 10 μm or less. The width of the first connection portion 21a refers to the width in the first direction X. The width of the first extending portion 21b refers to the width in a direction orthogonal to the direction in which the first extending portion 21b extends. In FIG. 1, the width of the first extending portion 21b refers to the width in the first direction X.

The first electrode 21 is made of a metal. For example, a metal such as copper (Cu), gold (Au), chromium (Cr), and aluminum (Al) can be used for the first electrode 21. The first electrode 21 may have a single-layer structure or a multilayer structure including a plurality of metal layers.

As shown in FIGS. 1 and 2 , the second electrode 22 is disposed on the second semiconductor layer 12b of the second light-emitting portion 42. The second electrode 22 is disposed on the light-transmissive conductive layer 13 disposed in the second light-emitting portion 42 and is electrically connected to the second semiconductor layer 12b via the light-transmissive conductive layer 13. In a top view, the second electrode 22 is disposed in a region in which the first insulating layer 14 is disposed. The light-transmissive conductive layer 13 is disposed between the second electrode 22 and the first insulating layer 14. The second electrode 22 includes a second connection portion 22a and a plurality of second extending portions 22b extending from the second connection portion 22a. The second connection portion 22a is a region connected to an external device via a wire or the like. As shown in FIG. 1, the second connection portion 22a has a substantially circular shape in a top view. The second extending portions 22b are electrodes used for efficiently diffusing the current supplied through the second connection portion 22a into the second semiconductor layer 12b of the second light-emitting portion 42. In a top view, the second extending portions 22b include curved portions. In the first direction X, a portion of the third electrode 23 is located in a region between portions of the second extending portions 22b.

In a top view, the width of the second extending portions 22b is less than the width of the second connection portion 22a. For example, the width of the second connection portion 22a is 40 μm or more and 80 μm or less. For example, the width of the second extending portions 22b is 3 μm or more and 10 μm or less. The width of the second connection portion 22a refers to the width in the first direction X. The width of the second extending portions 22b refers to the width in a direction orthogonal to the direction in which the second extending portions 22b extend.

The second electrode 22 is made of a metal. For example, the same metal material as for the first electrode 21 can be used for the second electrode 22.

The third electrode 23 is disposed on the second semiconductor layer 12b of the first light-emitting portion 41 and on the first semiconductor layer 12a of the second light-emitting portion 42 and electrically connects the first light-emitting portion 41 and the second light-emitting portion 42. The third electrode 23 has a first region 31 under which the first insulating layer 14 is disposed, the first region being in contact with the light-transmissive conductive layer 13, a second region 32 under which the first insulating layer 14 is not disposed, the second region being in contact with the light-transmissive conductive layer 13, and a third region 33 under which the first semiconductor layer 12a of the second light-emitting portion 42 is disposed, the third region 33 being electrically connected to the first semiconductor layer 12a of the second light-emitting portion 42. The second region 32 is located between the first region 31 and the third region 33 in a top view. The first region 31 and the second region 32 are continuous with each other in a top view. In the second direction Y, the second region 32 continuous with the first region 31 is located between the first region 31 and the third region 33. In FIG. 1, the first region 31, the second region 32, the third region 33, and a fourth region 34 described below are each indicated by hatching. In FIG. 2, in the portion indicating the third electrode 23, broken lines indicate the boundaries of the first region 31, the second region 32, the third region 33, and the fourth region 34 described below.

In a top view, the third electrode 23 in the first region 31 includes a curved portion. In the first direction X, a portion of the first extending portion 21b is located in a region between portions of the third electrode 23 in the first region 31.

The width of the third electrode 23 in the second region 32 is greater than the width of the third electrode 23 in the first region 31 in a top view. The concentration of current in the second region 32 can thus be reduced as compared with the case in which the width of the third electrode 23 in the second region 32 is equal to the width of the third electrode 23 in the first region 31. Accordingly, occurrence of breakage of the light-transmissive conductive layer 13 caused by damage can be reduced, and the reliability of the light-emitting element 10 can be enhanced. The width of the third electrode 23 in the first region 31 refers to the maximum width in a direction orthogonal to the direction in which the third electrode 23 extends, such as the width in the first direction X. The width of the third electrode 23 in the second region 32 refers to the maximum width in the first direction X.

The width of the third electrode 23 in the second region 32 can be 5 times or more and 10 times or less than the width of the third electrode 23 in the first region 31. Light absorption by the third electrode 23 can thus be reduced while reducing the concentration of current in the second region 32. For example, the width of the third electrode 23 in the first region 31 can be 3 μm or more and 10 μm or less. For example, the width of the third electrode 23 in the second region 32 is preferably 15 μm or more and 50 μm or less, more preferably 30 μm or more and 50 μm or less.

The third electrode 23 has the fourth region 34 under which the first insulating layer 14 is not disposed, the region being in contact with the second semiconductor layer 12b of the first light-emitting portion 41. In a top view, the second region 32 is located between the first region 31 and the fourth region 34. In a top view, the width of the third electrode 23 in the fourth region 34 can be equal to or greater than the width of the third electrode 23 in the second region 32. This structure enables the current to be less likely to be concentrated on the third electrode 23 in the fourth region 34 as compared with the case in which the width of the third electrode 23 in the fourth region 34 is less than the width of the third electrode 23 in the second region 32. For example, the width of the third electrode 23 in the fourth region 34 is preferably 15 μm or more and 50 μm or less, more preferably 30 μm or more and 50 μm or less. The width of the third electrode 23 in the fourth region 34 refers to the maximum width in the first direction X.

The width of a portion of the third electrode 23 located on the second insulating layer 15 is preferably equal to or greater than the width of the third electrode 23 in the second region 32. This structure enables the current to be less likely to be concentrated on the third electrode 23 located on the second insulating layer 15 as compared with the case in which the width of the portion of the third electrode 23 located on the second insulating layer 15 is less than the width of the third electrode 23 in the second region 32. For example, the width of the portion of the third electrode 23 located on the second insulating layer 15 is preferably 15 μm or more and 50 μm or less, more preferably 30 μm or more and 50 μm or less. The width of the portion of the third electrode 23 located on the second insulating layer 15 refers to the maximum width in the first direction X.

As shown in FIG. 1, in a top view, the third region 33 includes a first portion 331 continuous with a portion of the third electrode 23 that is located on the second insulating layer 15, and a second portion 332 continuous with the first portion 331. In a top view, the width of the first portion 331 is greater than the width of the second portion 332. The width of the second portion 332 is less than the width of the third electrode 23 in the second region 32. Light absorption by the third electrode 23 in the third region can thus be reduced as compared with the case in which the width of the second portion 332 is equal to or greater than the width of the third electrode 23 in the second region 32. For example, the width of the second portion 332 can be 3 μm or more and 10 μm or less. For example, the width of the first portion 331 is preferably 15 μm or more and 50 μm or less, more preferably 30 μm or more and 50 μm or less. The width of the first portion 331 in the third region 33 refers to the maximum width in the first direction X. The width of the second portion 332 in the third region 33 refers to the maximum width in the first direction X.

The third electrode 23 is made of a metal. For example, the same metal material as for the first electrode 21 can be used for the third electrode 23.

For example, the thicknesses of the first electrode 21, the second electrode 22, and the third electrode 23 can be 1 μm or more and 5 μm or less. The thickness of the first electrode 21, the thickness of the second electrode 22, and the thickness of the third electrode 23 may be the same or different from one another.

In a cross-sectional view, a conductive portion 50 is located between the third electrode 23 and the first semiconductor layer 12a of the second light-emitting portion 42. In a top view, the conductive portion 50 is continuously disposed over the first light-emitting portion 41 and the second light-emitting portion 42. The conductive portion 50 is in contact with the first semiconductor layer 12a of the second light-emitting portion 42 and the second insulating layer 15 and is not in contact with the second semiconductor layer 12b of the first light-emitting portion 41. The conductive portion 50 is in contact with the first semiconductor layer 12a of the second light-emitting portion 42 and electrically connected to the first semiconductor layer 12a of the second light-emitting portion 42. The conductive portion 50 continuously disposed over the first light-emitting portion 41 and the second light-emitting portion 42 may not necessarily be disposed. In this case, the third electrode 23 is in contact with the first semiconductor layer 12a of the second light-emitting portion 42 and the second insulating layer 15.

A portion of the conductive portion 50 is located on the second insulating layer 15 located on the second semiconductor layer 12b of the first light-emitting portion 41. Among the light from the active layer 12c, light traveling toward the third electrode 23 is thus reflected by the conductive portion 50, so that light absorption by the third electrode 23 located on the second insulating layer 15 can be further reduced.

The conductive portion 50 may be disposed between the first electrode 21 and the first semiconductor layer 12a of the first light-emitting portion 41. The conductive portion 50 is electrically connected to the first semiconductor layer 12a of the first light-emitting portion 41. In a top view, the first electrode 21 is located in a region in which the conductive portion 50 is disposed. Among the light from the active layer 12c, light traveling toward the first electrode 21 is thus reflected by the conductive portion 50, so that the light absorption by the first electrode 21 can be reduced.

For example, the conductive portion 50 preferably contains a metal that is highly light-reflective at a peak emission wavelength of light from the active layer 12c. For example, as the metal used for the conductive portion 50, a metal having a reflectance of 60% or more, preferably 70% or more, at the peak emission wavelength of the light from the active layer 12c is preferably used. For example, Al or a metal material containing Al can be used for the conductive portion 50.

A protective layer 60 covers substantially the entire upper surface side of the light-emitting element 10. As shown in FIGS. 1 and 2, the protective layer 60 has openings in the respective regions in which the first electrode 21, the second electrode 22, and the third electrode 23 are disposed. The first electrode 21, the second electrode 22, and the third electrode 23 are respectively disposed in the openings of the protective layer 60.

A light-transmissive and insulating material is preferably used for the protective layer 60. For example, a silicon oxide film, a silicon oxynitride film, or a silicon nitride film can be used for the protective layer 60.

While the light-emitting element according to the present invention has been specifically described referring to the embodiment, the scope of the present invention is not limited by these descriptions and should be broadly interpreted on the basis of the claims. The scope of the present invention also encompasses various variations based on these descriptions.

### Industrial Applicability

The light-emitting element of the present invention can be used for various light sources such as backlight sources for liquid-crystal displays, various lighting apparatuses, and large screen displays.

What is claimed is:

1. A light-emitting element comprising:
a substrate;
a first light-emitting portion and a second light-emitting portion disposed on the substrate, the first light-emitting portion and the second light-emitting portion each comprising a first semiconductor layer of a first conduction type, a second semiconductor layer of a second conduction type, and an active layer between the first semiconductor layer and the second semiconductor layer;
a first insulating layer disposed on a portion of the second semiconductor layer of the first light-emitting portion;
a light-transmissive conductive layer disposed on the first insulating layer and on the second semiconductor layer of the first light-emitting portion;
a first electrode disposed on the first semiconductor layer of the first light-emitting portion and electrically connected to the first semiconductor layer of the first light-emitting portion;
a second electrode disposed on the second semiconductor layer of the second light-emitting portion and electrically connected to the second semiconductor layer of the second light-emitting portion; and
a third electrode disposed on the second semiconductor layer of the first light-emitting portion and on the first semiconductor layer of the second light-emitting portion to electrically connect the first light-emitting portion and the second light-emitting portion, wherein:
the third electrode comprises a first region under which the first insulating layer is disposed and in contact with the light-transmissive conductive layer, a second region under which the first insulating layer is not disposed and in contact with the light-transmissive conductive layer, and a third region under which the first semiconductor layer of the second light-emitting portion is disposed, the third region being electrically connected to the first semiconductor layer of the second light-emitting portion,
the second region is located between the first region and the third region in a top view, and
a width of the third electrode in the second region is greater than a width of the third electrode in the first region in a top view.

2. The light-emitting element according to claim 1, wherein:
the third electrode further comprises a fourth region under which the first insulating layer is not disposed and in contact with the second semiconductor layer of the first light-emitting portion,
the second region is located between the first region and the fourth region in a top view, and
a width of the third electrode in the fourth region is equal to or greater than the width of the third electrode in the second region in a top view.

3. The light-emitting element according to claim 1, further comprising:
a second insulating layer disposed on a portion of the substrate located between the first light-emitting portion and the second light-emitting portion and on the first semiconductor layer of the first light-emitting portion, wherein:
a thickness of the second insulating layer is greater than a thickness of the first insulating layer.

4. The light-emitting element according to claim 2, further comprising:
a second insulating layer disposed on a portion of the substrate located between the first light-emitting portion and the second light-emitting portion and on the first semiconductor layer of the first light-emitting portion, wherein:
a thickness of the second insulating layer is greater than a thickness of the first insulating layer.

5. The light-emitting element according to claim 1, further comprising:
a second insulating layer disposed on a portion of the substrate located between the first light-emitting portion and the second light-emitting portion in a top view, on the first semiconductor layer of the first light-emitting portion, and on the second semiconductor layer of the first light-emitting portion, wherein:
a width of a portion of the third electrode located on the second insulating layer is equal to or greater than the width of the third electrode in the second region.

6. The light-emitting element according to claim 2, further comprising:
a second insulating layer disposed on a portion of the substrate located between the first light-emitting portion and the second light-emitting portion in a top view, on the first semiconductor layer of the first light-emitting portion, and on the second semiconductor layer of the first light-emitting portion, wherein:
a width of a portion of the third electrode located on the second insulating layer is equal to or greater than the width of the third electrode in the second region.

7. The light-emitting element according to claim 3, further comprising:
a second insulating layer disposed on a portion of the substrate located between the first light-emitting portion and the second light-emitting portion in a top view, on the first semiconductor layer of the first light-emitting portion, and on the second semiconductor layer of the first light-emitting portion, wherein:
a width of a portion of the third electrode located on the second insulating layer is equal to or greater than the width of the third electrode in the second region.

8. The light-emitting element according to claim 1, wherein a width of the third electrode in the third region is less than the width of the third electrode in the second region in a top view.

9. The light-emitting element according to claim 2, wherein a width of the third electrode in the third region is less than the width of the third electrode in the second region in a top view.

10. The light-emitting element according to claim 3, wherein a width of the third electrode in the third region is less than the width of the third electrode in the second region in a top view.

11. The light-emitting element according to claim 3, wherein the thickness of the second insulating layer is twice or more and four times or less than the thickness of the first insulating layer.

12. The light-emitting element according to claim 7, wherein the thickness of the second insulating layer is twice or more and four times or less than the thickness of the first insulating layer.

13. The light-emitting element according to claim 10, wherein the thickness of the second insulating layer is twice or more and four times or less than the thickness of the first insulating layer.

14. The light-emitting element according to claim 1, wherein the width of the third electrode in the second region is 5 times or more and 10 times or less than the width of the third electrode in the first region.

15. The light-emitting element according to claim 2, wherein the width of the third electrode in the second region is 5 times or more and 10 times or less than the width of the third electrode in the first region.

16. The light-emitting element according to claim 1, wherein the light-transmissive conductive layer contains indium tin oxide or zinc oxide.

17. The light-emitting element according to claim 1, wherein the first insulating layer contains silicon oxide film, silicon oxynitride film, or silicon nitride film.

18. The light-emitting element according to claim 1, wherein the second insulating layer contains silicon oxide film, silicon oxynitride film, or silicon nitride film.
